(19) United States
(12) Patent Application Publication
(10) Pub. No.: US 2008/0144293 A1
(43) Pub. Date: Jun. 19, 2008

(54) Cable Management System and Method for Rack Mountable Equipment

(75) Inventors: Slavek P. Aksamit, Durham, NC (US); David D. Chudy, Raleigh, NC (US); Cristian Medina, Durham, NC (US)

Correspondence Address: IBM COPORATION (RTP);C/O SCHUBERT OSTERRIEDER & NICKELSON PLLC, 6013 CANNON MOUNTAIN DRIVE, S14, AUSTIN, TX, 78749, US

(73) Assignee: INTERNATIONAL BUSINESS MACHINES CORPORATION, Armonk, NY (US)

(21) Appl. No.: 11/613,002

(22) Filed: Dec. 19, 2006

(51) Int. Cl. H05K 7/14; B23P 11/00

(52) U.S. Cl. 361/727; 29/428

(57) ABSTRACT

In accordance with the present disclosure, a drawer slide rack equipment mount that allows an equipment chassis to be operational when the chassis is slid in the rack and when the chassis is slid outward from the rack such that components in the chassis can be tested while the components are operating as part of the rack system. The drawer slide can include a first rigid member and a second rigid member to slidably engage the first rigid member. Also a set of contacts holders can hold contacts proximate to the first rigid member and in a parallel configuration with the first rigid member such that when conductors on an equipment chassis (and a second rigid member) move with the second rigid member along the first rigid member the set of contacts mounted in relation to the first rigid member can engage the conductors on the equipment chassis in more than one location.

### FIELD OF THE DISCLOSURE

The present disclosure is generally related to rack mounted electronic equipment and more particularly to systems and methods for securing electrical connections to rack mounted equipment.

### BACKGROUND

Large electronic systems are typically created by combining numerous functionally distinct pieces of electronic equipment. Generally, each system has different functional requirements and rack mountable electronic equipment can be purchased from different vendors and integrated into, and secured by equipment racks to form a complete system. For example, a business may need a mail server, a voice over Internet protocol server, a web page server, a business phone system and a large amount of data storage and they can all be integrated in to an equipment rack. Other system installations such as “server farms,” can require a mouse, keyboard, and video monitor to be connected to each server. This equipment can be purchased from the individual vendors, mounted in a rack, and then interconnected with wires and cables to form an operational system.

Rack mountable equipment comes in many shape and sizes and different equipment typically has different connector configurations, often making installation and cabling of the equipment a formidable task. Many rack installations will have cables and wires running multiple directions in the rack causing an unsightly installation. A robust equipment installation typically requires electrical connections between many different types of equipment within the rack. Further, rack-mounted equipment often requires interconnection to equipment mounted external to the rack.

Many industry standards and specifications exist that specify sizes of rack, shelves and slides for the rack and so on. One such specification is the network equipment building system, (NEBS) guidelines. NEBS guidelines include a set of technical requirements, that when complied with, make rack mounted equipment more resistant to failures. The NEBS standard was initially developed by Bell Labs® for the telecommunications industry. However, the NEBS standard is often utilized as a guideline in many other industries that utilize rack mounted equipment. Thus, many industries and customers strive to meet the specific mechanical requirements provided by the NEBS guidelines.

The spacing of vertical fastening members within commercially available racks and the spacing of the holes in the vertical members are dictated by another set of guidelines, the electronics industry alliance (EIA) guidelines. The EIA guidelines provide standard mounting hole dimensions for equipment racks. A typical EIA compliant rack will have two vertical members at the front of the rack and two vertical members at the rear of the rack. Specific spacing is typically provided between the vertical rack members and between the holes within these members. EIA compliant racks can be purchased in different standard widths to accommodate equipment chassis that are, for example 24, 28, or 30 inches wide. Equipment chassis typically meet this standard and equipment chassis are typically shaped like a “rectangular box” such that they can be easily inserted into the rack, fastened to the rack and removed when needed, for example when the equipment breaks down or requires testing or troubleshooting. Some racks systems are specifically made to perform as a test platform for individual rack equipment.

In a typical or “non-test platform” rack, cabling is typically fastened to the back of the equipment chassis via connectors. When equipment is being tested or serviced in a conventional rack installation, the rear connectors must be unfastened from the equipment chassis and the chassis must be unbolted and removed from the rack. The covers from the chassis can then be removed and the chassis can then be placed in a custom test fixture and tested. Removal of the covers allows a technician to place electrical probes and test connectors into the circuits contained in the chassis to aid in diagnosing a problem. Such customized test fixtures are very expensive and often not available. Thus, for numerous reasons it is important to be able to test rack mounted equipment while it is installed into a rack and operating with an entire system. However, access to internal components of rack mounted equipment for testing and analysis is virtually impossible when the equipment chassis is secured within the rack. It can be appreciated that access to components in a chassis typically requires removal of covers of the equipment chassis and such removal is often not possible when the chassis is installed in the rack.

In some system installations, the installers place a large cable service loop (several feet of excess cable) at the back of the rack such that the equipment to be serviced can be unsecured from the rack, placed on a bench or table next to the rack, (sometimes at the back of the rack) while remaining connected to the system. When the equipment is removed and the cover(s) taken off on the bench, test connectors or test probes can be connected to circuit boards or components within the equipment chassis to monitor operation and diagnose problems. Such large service loops and excess cabling can cause significant problems and add to the cost of a rack installation. Further, access to such components allows a technician to replace circuit boards and other components possibly “hot swapping” such components while keeping the system operational.

One troubling issue for rack-mounted systems/equipment is the lack of a standard and efficient way to interconnect equipment. For example, many systems exist that have well defined bus architectures, however interconnecting such equipment is, by no means a simple or standard procedure. In fact, fabricating system interconnects is often very labor intensive and more particular such custom interconnection designs are hard to document.

As stated above, it is cumbersome and time consuming for a technician or installer to install cabling and document the interconnections and a more automated cabling process would be beneficial. It is a further burden to make a rack mounted system installation where the installed equipment is easily serviceable and testable while the equipment is electrically connected to the system and functioning as part of the system. This is particularly true when a rack is fully populated because access space can be very limited. In view of the above-described disadvantages associated with current systems and methods for interconnecting rack mounted equipment such that the equipment is serviceable, testable and operational while installed in an equipment rack, there is a need for improvements in this field.

### SUMMARY OF THE INVENTION

The problems identified above are in large part addressed by methods and arrangements disclosed herein to provide easy installation and servicing of rack mountable equipment. In one embodiment, an equipment mounting and interconnect apparatus is disclosed. The apparatus can include a drawer slides with integrated mating contacts on each portion of the slide. The drawer slides can mount between an equipment chassis and vertical members of an equipment rack. The drawer slides can allow the equipment chassis to be fully pushed into the rack and fully extended from the rack and during such a transition between “in-and-out” the components in the equipment chassis can maintain electrical continuity with peripheral devices or other equipment in the rack via the contacts. Such continuity can also be achieved via contacts on the side of the equipment chassis that slide along contacts that are fixed to the rack where the contacts can be mounted along the length of the drawer slide in parallel with the motion provided by the drawer slide.

Thus, a left rail and right rail or drawer slides can secure electrical contacts. The rails can be installed into a rack and an equipment chassis with spring loaded contacts on its side walls can be installed into the rack via a mechanical connection to the rail such that the chassis contacts can mate with the rail contacts. Accordingly, an electrical connection between rack mounted equipment can be achieved automatically without the fabrication of cabling. Such a connection can be achieved via the sliding contact engagement system between the chassis and the contacts fixed in relation to the rails. When it is desired to test the components within a chassis mounted in the rack, the chassis can be slid outward from the rack on the drawer slides, such that the components in the chassis are exposed and can be accessed. During such a sliding process the components can remain electrically connected to, and remain an operational part of the system via the drawer slide connection system.

In another embodiment, the apparatus can include a first rigid member securable in a rack perpendicular to vertical members in the rack. The first rigid member can have a first end and a second end. A second rigid member can be configured to slidably engage the first rigid member and the second rigid member can be attached to the insertable chassis. A plurality of electrical contacts can be assembled proximate to the first rigid member (possibly to the side of the rack) and in a parallel relationship with the first rigid member such that conductors mounted on the insertable chassis can contact with the plurality of electrical contacts as the insertable chassis is slid or moved in relation to the rack.

The rigid rail members could utilize/confine ball bearings or Teflon® between them to reduce the friction when sliding in relationship to each other. The chassis can be moved from a fully inserted position to a cantilevered position where covers on the chassis can be removed and internal components of the equipment can be accessed and tested. The contacts mounted to the rack side and to the chassis side of the slide can be secured in a connector housing or can be mounted on or secured by a printed circuit board. In one embodiment, the contacts on the chassis can be wipers and the contacts on the rack side can be tracks or a long narrow traces on the circuit board that generally run parallel to the first and second end of the first rigid member.

In one embodiment, the tracks, (i.e. long narrow traces or contact strips) can be runners of plated copper having lengths that are over ten times their width. Thus, one of the set of contacts (either the chassis secured contacts of the rack secured contacts) can be long and narrow. Possibly the long narrow contacts can be part of a long narrow circuit board where the traces are configured in a linear parallel relationship to at least one load-bearing surface of the first rigid member. This allows spring loaded contacts on the sliding chassis to slide along the long narrow traces and maintain electrical contact as the chassis is moving in relation to the rack. In addition, when not sliding but at a rest position, the chassis can also remain connected and operational.

In another embodiment, a first contact housing can be located proximate to the first end of the first rigid member and a second contact housing can be located proximate to the second end of the first rigid member wherein the first and second contact housings can be located in a parallel relationship with the first and second end of the first rigid member. The chassis can have a set of spring loaded contacts. Thus, the chassis can be located in two different “locked” locations (fully inserted and fully extended) wherein at the first location the contacts on chassis will engage the contacts in the first housing and at the second location the contacts on the chassis will engage the contacts in the second housing. The circuit board or the contacts affixed to the chassis can be spring loaded to bias the contacts together with the rack based contacts to accommodate production and design tolerances.

The apparatus can also include a matching/mating set of drawer slides for the other edge/side of the equipment chassis that includes a third rigid member securable in the rack, perpendicular to the vertical members in the rack. The third rigid member can also have a first end and a second end. A fourth rigid member can be configured to slidably engage the third rigid member and can also be attached to the insertable chassis. Another set of electrical contacts, can be assembled on another side of the rack in a parallel relationship with the third rigid member. This may allow conductors mounted on a second side of the insertable chassis to contact with the second set of electrical contacts on the insertable chassis. This can increase the number of contacts available for a chassis with a predetermined, possibly small side wall dimension. Thus, as stated above, the insertable chassis can be moved to at least two positions in relationship to the rack while it is mechanically and electrically connected to the rack/system and the equipment can utilize the first and second set of contacts on each side of the chassis to receive a power and ground and to communicate information.

In another embodiment, an equipment mounting system is disclosed. The system can include a first rail mountable horizontally between a first and second vertical member in an equipment rack. The equipment rack can have a periphery or physical outer boundary. A second rail can be mounted horizontally between a third and fourth vertical member in the equipment rack. The first and second rail can guide the equipment chassis as the chassis is fully inserted into the periphery of the rack or slid out of the periphery of the rack.

The system can also mount a set of contacts affixed with the rack and disposed in a parallel configuration with the first rail such that a set of conductors mounted on the equipment chassis can engage the set of contacts secured by the chassis when the chassis is inserted into the rack and, can remain engaged when a portion of the chassis is outside of the periphery of the rack. In one embodiment the set of conductors can interconnect a uniform serial bus (USB) between the chassis and peripheral devices.

In another embodiment the manufacturing of an equipment rail such as a drawer slide is disclosed. Manufacturing the drawer slide can include forming a first rigid member and forming a second rigid member to slidably engage the first rigid member. Also a set of contact holders can be formed to hold contacts proximate to the rack mounted location of the first rigid member and in a parallel configuration with the first rigid member. Accordingly, when conductors on an equipment chassis (proximate to the second rigid member) that is inserted into the rack can move with the chassis along the first rigid member, and the set of contacts mounted in the rack proximate to the first rigid member can engage the conductors on the equipment chassis in more than one location.

Further, a printed circuit board can secure connectors, contacts and cables in both the chassis on the rack proximate to the first rigid member. A connector can be assembled on the printed circuit board such that a cable or another circuit board can interconnect numerous rails mounted to the rack.

### BRIEF DESCRIPTION OF THE DRAWINGS

Advantages of the invention will become apparent upon reading the following detailed description and upon reference to the accompanying drawings in which, like reference numbers may indicate similar elements:

FIG. 1 depicts an orthogonal front view of an equipment rack or cabinet having equipment chassis, drawer slides and contacts members for interconnection of electronic equipment;

FIG. 2 depicts a cross sectional view of a sliding assembly and contacts disposed in the same plane as the sliding assembly; and

FIG. 3 depicts a flow diagram of a method for making an equipment mount with a continuous slidable electrical interconnection system.

### DETAILED DESCRIPTION OF THE DRAWINGS

The following is a detailed description of novel embodiments depicted in the accompanying drawings. The embodiments are in such detail as to clearly communicate the subject matter. However, the amount of detail offered is not intended to limit anticipated variations of the described embodiments; but on the contrary, the claims and detailed description are to cover all modifications, equivalents, and alternatives falling within the spirit and scope of the present teachings as defined by the appended claims. The detailed descriptions below are designed to make such embodiments understandable to a person having ordinary skill in the art.

Generally, methods and arrangements to efficiently mount and electrically interconnect rack mounted equipment are disclosed. While specific embodiments will be described below with reference to equipment interconnect configurations, those of skill in the art will realize that embodiments of the present disclosure may advantageously be implemented with other components and configurations. The methods and arrangements described herein can be effectively utilized to; efficiently mount equipment of various dimensions into a rack, to electrically interconnect such equipment utilizing slidable contacts and to test such equipment in multiple positions while the equipment remains functioning as part of the rack system.

In accordance with the present disclosure, a rack equipment mounting system is described that can utilize a drawer slide type mounting apparatus to mount an equipment chassis and bulkhead type connections to electrically interconnect the chassis to other rack equipment via contacts fixed proximate to the mounting rail. Further, a cableless interconnect is disclosed for connecting components in the equipment chassis to a series of ports mounted on the rack. Such an electrical interconnect is provided while the equipment chassis is fully slid into the rack on the drawer slide and when the drawer slide is fully extended and the equipment chassis is cantilevered outside of the rack. This multi-position cableless interconnect can be accomplished by placing contacts along the side of the rack proximate to the rack mounted slide such that contacts on the side of the equipment chassis can contact the contacts mounted by the rack as the equipment chassis is slid in relation to the rack.

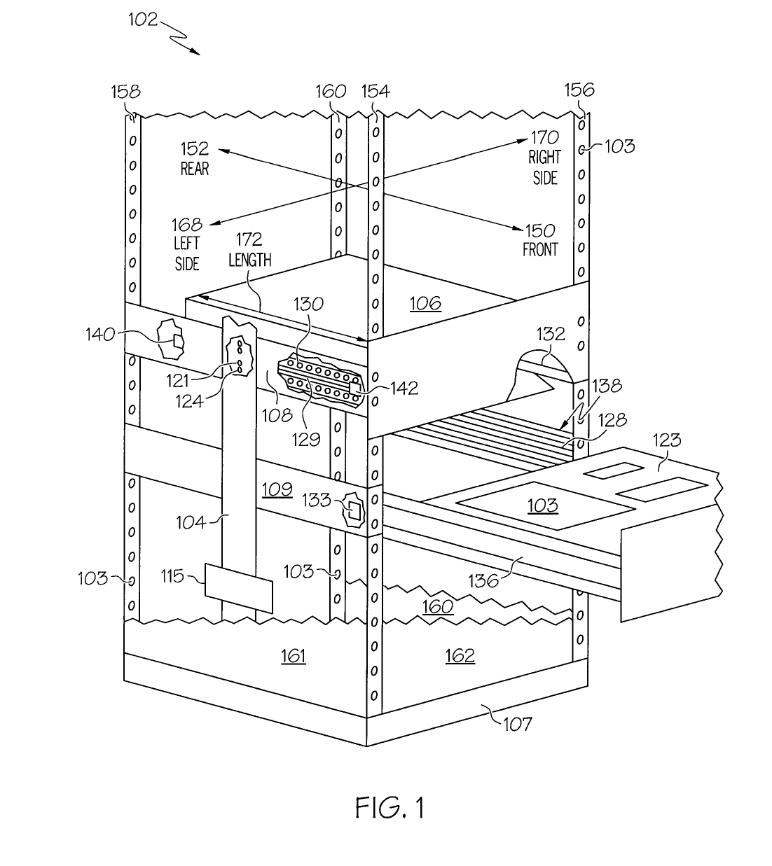

Referring to FIG. 1, a cut away view of a portion of a rack 102 for mounting electronic equipment is illustrated. A typical rack installation can have side covers 160 and 161 and a front door 162, all depicted cut away except for the lower portion of the rack 102. Side covers 160 and 161 and a front door 162 have been “cut away” to illustrate the rack mounting and electrical connection features of the present disclosure. For reference, a coordinate axis has been provided to illustrate the front of the rack 150, the rear of the rack 152, the left side of the rack 168, and the right side of the rack 170.

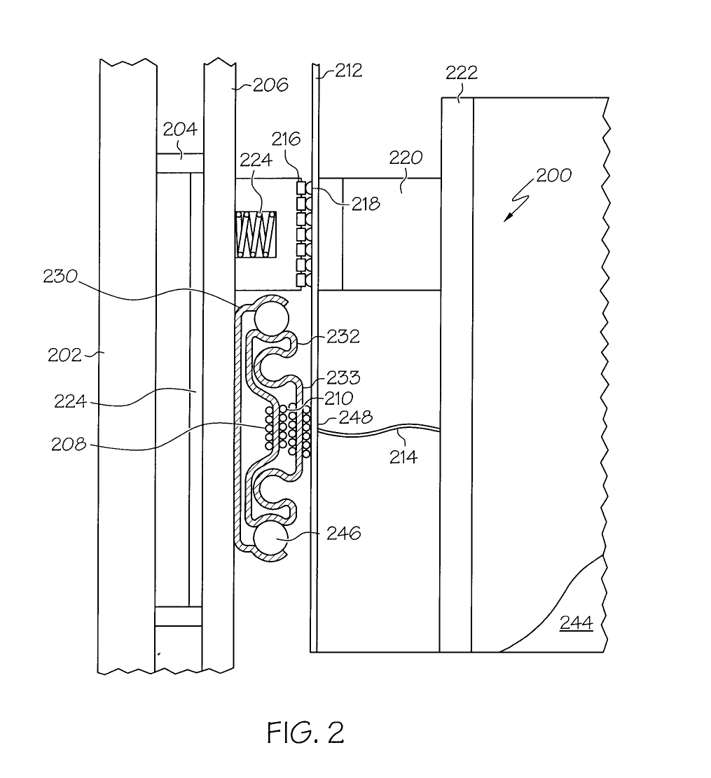

Although the mounting and interconnect system is describe in the context of inserting equipment into the front of the rack 150, inserting equipment from the rear of the rack 152 would not part from the embodiments contemplated. Likewise, some descriptions such as FIG. 2 below focus on a single rail on the left side 168 of the rack 102. However, a similar description can be applied to the rail on the right side 170 of the rack 102. As stated above, a rack can be selected for an installation based on a desired width as measured from the left side of the rack 168 to the right side of the rack 170 and for a desired depth from the front 150 of the rack 102 to the back 152 of the rack 102. Such configurations would not part from the scope of this disclosure.

The rack 102 can include front vertical members 154 and 156 and rear vertical members 158 and 160, collectively referred to as (vertical members 154-160). The vertical members 154-160 can be secured about a base 107 and about a top cap (not shown). Vertical members 154-160 can have a cross section resembling an “L” shape. Thus, the vertical members 154-160 can be formed by bending a flat bar at a ninety degree angle or they can be made from angle stock to give the vertical rails 154-160 improved rigidity. The vertical members 154-160 can have a series of holes 103 that are spaced up and down the vertical members 154-160. The holes 103 in the vertical members 154-160 can be evenly spaced in three dimensions within the rack 102 in accordance with industry standards.

An equipment chassis, such a chassis 106 and 123 can have a width that is compatible with the width of the rack 102 such that they can be installed on sliding surfaces in the rack 102. A typical chassis will be a rectangular shape box having four corners and will have a predefined length 172. Generally, nearly any length of chassis 172 can be accommodated by the teachings of the present disclosure. The chassis 106 can be mounted into the rack 102 on a sliding assembly. This type of sliding assembly is commonly referred to as a drawer slide. Left side drawer slides 108 and 109 can be embodied as a two part track or a three part track. A three part track is commonly referred to as a telescoping drawer slide. Drawer slide 108 can mount chassis 106 on the left side 168 of the rack 102 and drawer slide 132 can mount chassis 106 on the right side 170 of the rack 102.

Further, drawer slide 109 can mount chassis 123 on the left side 168 of the rack 102 and drawer slide 138 can mount the chassis 123 on the right side 170 of the rack 102. Further, drawer slide 108 (as with all drawer slides) can include a first rigid member attached to the rack 102 and a second rigid member attached to the chassis 106. Generally, a load bearing surface and possibly ball bearings 130 can be retained between two rigid members that make up the drawer slide 108. Prior to installing the equipment chassis 106 in the rack 102, mounting rails or drawer slides 108, 109, 132 and 138 can be installed between front vertical member 154 and rear vertical member 158 of the rack 102. Each drawer slide can have a first end that is connected at the front of the rack 102 and a second end that is connected at the rear of the rack 152 respectively.

Each drawer slide 108, 109, 132 and 138 can be disassembled into two pieces, where one rail or rigid member can be mounted to the rack 102 and the other rigid member can be mounted to the chassis (i.e. 106 and 123). After such mounting, the rigid members can mate and be slidably engage with each other. The rigid members can retain ball bearings 130, a Teflon® surface or some other material or method such that the chassis 123 can be slid in-and-out of the rack 102. Chassis 106 is illustrated inserted into the rack 102 or within the periphery of the rack 102 and chassis 123 is illustrated extended out and cantilevered from the rack 102 allowing access to components 103 within the chassis 123. When chassis 123 is near the end of the travel of the drawer slides 109 and 138 a stop mechanism can keep the chassis 123 from being “pulled out” of the rack 102 without activating the stop mechanism (not shown).

Activating this mechanism can allow a multi-piece drawer slide to be separated such that when both drawer slides (a left and a right 109 and 138) are separated, the chassis 123 can be detached from the rack 102. Such a mechanism typically allows the drawer slide to be separated where one piece can remain attached to the rack 102 and one piece can remain attached to the chassis 123. Such a configuration also aids in the installation procedure. Thus, in the illustration, two internal rails of the drawer slides can be attached to the chassis 123 and their mating external rails of the drawer slide can be attached to vertical members 154 and 158 of the rack 102.

In accordance with the present disclosure, individual conductive traces 129 shown in a cut away window (only two shown for illustrative purposes more shown as conductive traces 128) can be secured proximate to the rail in parallel relationship to the drawer slide 108 and 138. Spring loaded pins or wipers in a housing 142 mounted or mechanically secured to a side wall of the chassis 106 can engage the conductive traces 129 and 128 as the chassis 106 is slid in and out of the rack 102. Thus, regardless of the location of the chassis 106 in relation to a particular location of the rack 102, the components in the chassis 106 can remain electrically connected and operational with the system via the wipers and the conductive traces 128 and 129.

In one embodiment, the conductive traces 128 and 129 can be assemble on one side of a circuit board that is mounted to the rack 102 or the rail 108 and 138 and contacts 121 and a connector can be placed on an opposite side of the circuit board to mate with contacts on a vertically mounted circuit board 104. Contacts 121 can engage contacts 124 on a vertically mounted circuit board 104 where vertically mounted circuit board 104 can interconnect the rail based contacts and in turn provide a cableless interconnect for components in different equipment chassis (i.e. 123 and 106).

Thus, components in chassis 106 can interconnect to components 102 in chassis 123 without the need for cables. Thus, much of the labor typically required to do a rack installation can be avoided in accordance with the present disclosure. For example, no stripping of wire insulation is required, no hand crimping of pins to the wires is required, no connector fabrication is required and assembly of connector housings/strain relief is also avoided. Further, the requirement of stamping codes on wires, fabricate cables and dressing wires and cable in the rack is also eliminated. Yet further there is no need for service loops.

In addition chassis components, such as components 102 can be exposed or accessible for testing during system operation without planning for such access during fabrication of the equipment rack 102. One additional benefit is that cabling drawings can be foregone in favor of existing schematics. As can be appreciated, as the chassis 106 is slid in and out of the rack system 102 circuit boards and other electrical components within the chassis can maintain constant electrical contact with the side plane circuit board 104.

In one embodiment, a junction box 115, hub or port can be manufactured on the circuit board 104 to provide a bus connection between the rack mounted equipment and peripheral equipment or devices. In a specific embodiment, peripheral devices such as a keyboard, video, mouse can be connected to the junction box 115. The junction box 115 could be a keyboard, video monitor, mouse switch, (KVM switch) that can switch a uniform serial bus from a single keyboard to multiple computers or servers in the rack 102.

The junction box 115 can be assembled to circuit board 104 at a convenient location possibly having connectors protruding through side panel 161 such that an external access port is provided. With such a switch/port, a single keyboard, video monitor and mouse (not shown) can placed on a shelf in the rack 102 or beside the rack 102 on a desk or bench and plugged into the junction box 115 or KVM switch. The KVM switch can allow the keyboard, monitor and mouse to control more than one computer or server mounted in the rack 102 at one time. Alternately, a user can utilize the KVM switch such that the keyboard monitor and mouse can control a selected piece or equipment (i.e. one computer, server etc. at a time).

If the rack 102 is populated with numerous servers, the circuit board interconnection with the hub 115 or KVM switch can be an efficient way to interconnect a single peripheral or set of input devices to more than one computer or server. Such a KVM switch or uniform serial bus hub (USB) is valuable for a system administrator to monitor many different servers in a “server farm” environment. Generally, it may only be necessary for the administrator to periodically access each separate computer or server in the farm one at a time and a single switch port provides many benefits.

In an alternate embodiment, instead of continuous strips of conductive traces 129 along the rack mounted rail 108, and traces 128 along rail 138, two sets of identically ordered contacts (rear contacts 140 and front contacts 142 and also front connector 132) can be placed at each end of the rail 108 such that the chassis 106 can be electrically connected when fully slid into the rack 102 and when full extended outside of the rack 102. Alternately described, instead of contact traces/strips 128, 129 being placed down the entire length of the drawer slide or rail 108, the rail 108 may only have contacts dispose to mate with a connector on the chassis 123, when the chassis 123 is fully inserted and fully extended, but not at locations in between such locations. Such connection points can be located parallel to the rail bearing surface and are illustrated generally by connectors securing contacts 140 and 142 at each end of the rail 108.

Referring to FIG. 2 a cross sectional view of a rack mounting/interconnect system 200 is depicted. Generally, a rigid member or rail 230 can be attached to at least one vertical member 206 in an equipment rack 202. Rigid members or rails 232 and 233 can be secured to a chassis 244 (shown with a portion cut away) and disposed to move parallel to and slidably engage the rack mounted rail 230. When engaged, the rails 230, 232 and 233 can slidably secure the chassis 244 to the rack 202. Ball bearings such as ball bearing 246 can minimize the sliding friction as the chassis 244 is slid into or out of the rack 202. For simplicity, only one rail or sliding assembly is illustrated in FIG. 2 as a second rail (not shown on the opposite side of the chassis 244) could secure an opposite side of the chassis 244 to a second sidewall of the rack 202 (not shown).

Thus, as stated above, when a chassis 244 is slid in relation to rail 230 and in relation to the rack 202, at different locations in the sliding process, rack secured contacts 216 can engage chassis secured contacts 218. When the contacts 216 and 218 are engaged components such as circuit board 222 and discrete components (not shown) within the chassis 244 can be electrically connected to other equipment mounted by the rack 202 and to equipment not mounted to the rack 202 via connector housing 220 and contacts 216 which can make a cableless connection. Chassis wall 212 can mount the connector housing 220 and accurately locate contacts 218 in relationship to the rails 232 and 233. A conductor securing apparatus such as a circuit board or a connector housing that secures contacts 216 can be spring loaded with spring 225 such that the contacts 216 and 218 are biased together.

In one embodiment, contacts 216 and 218 can be mounted proximate to the rails 230 and 232 (above and/or below the load bearing connection and in another embodiment the contacts can be mounted between two load bearing surfaces as depicted by contacts 208, 248, and 210. Conductor 214 illustrates another connection between circuit board 222 within the chassis 244 and conductors mounted by the rack 202. The rails 230 and 232 can have flanges, rollers, ball bearings, Teflon pads and other mechanisms to ease the friction and to provide alignment of the contacts (i.e. 216 and 218).

As disclosed above, with reference to FIG. 1, a vertically mounted circuit board 224 can connect contacts 216 to contacts on other shelves in the rack 202. The vertically mounted circuit board can be secured by hardware 204. The vertically mounted circuit board 224 can be coupled to contacts 216 and can convey signals from circuit board 222 to circuit boards that are assembled in other servers (not shown) and possibly to a port or a KVM switch.

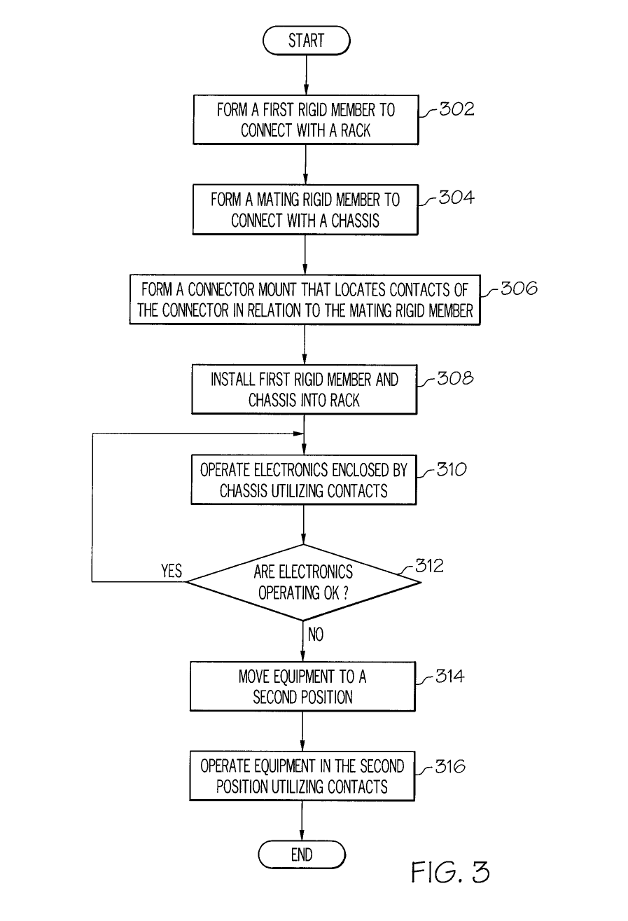

Referring to FIG. 3, a flow diagram for manufacturing a rack equipment interconnect system and testing operating rack mounted equipment is provided. As illustrated by block 302, a first rigid member can be formed. The first rigid member can be manufactured such that is can be connected to an equipment rack. As illustrated by block 304, a second rigid member can be formed that will slidably engage with mate with the first rigid member. The two rigid members can be configured to retain ball bearings or alternately to secure a low friction surface such as a Teflon® surface. Such an assembly can be referred to generically as a drawer slide. The second rigid member can be formed such that it can be connected to a side of a rack mountable equipment chassis.

As illustrated by block 306, a connector mount can be fabricated that can mount contacts in a fixed relationship with the first rigid member such that when the equipment chassis and the second rigid member is in different positions in relation to the first rigid member and the rack the contacts can mate with a set of contacts on the equipment chassis or possibly the second rigid member.

As illustrated by block 308, the chassis and the first rigid member can be installed into an equipment rack. The equipment chassis can be operated in a first position in relationship to the rack utilizing contacts that are aligned with the first rigid member. The chassis mounted contacts can mate with the rack mounted contacts to conduct power and electrical signals throughout the rack, as illustrated by block 310.

At decision block 312, it can be determined if the equipment is operating correctly. If the equipment is operating correctly then the process can revert back to block 310 where the equipment can continue to operate in the first position. When at block 312, it is determined that the equipment is not operating properly, then the equipment can be moved to a second position. The second position can be a position where the equipment chassis can be moved out from the equipment rack such that covers of the chassis can be removed allowing user access to components within the equipment chassis. As illustrated by block 316, the equipment can be operated in the second position utilizing the contacts on the equipment chassis and the contacts mounted in the fixed relationship to the first rigid member (or the rack). The process can end thereafter.

Another embodiment is implemented as a program product for implementing a design simulation to simulate one or more of the methods and arrangements described with reference to FIGS. 1-3. The program(s) of the program product defines functions of the embodiments (including the methods described herein) and can be contained on a variety of data and/or signal-bearing media. Illustrative data and/or signal-bearing media include, but are not limited to: (i) information permanently stored on non-writable storage media (e.g., read-only memory devices within a computer such as CD-ROM disks readable by a CD-ROM drive); (ii) alterable information stored on writable storage media (e.g., floppy disks within a diskette drive or hard-disk drive); and (iii) information conveyed to a computer by a communications medium, such as through a computer or telephone network, including wireless communications. The latter embodiment specifically includes information downloaded from the Internet and other networks. Such data and/or signal-bearing media, when carrying computer-readable instructions that direct the functions, represent embodiments.

In general, the routines executed to implement the designing embodiments, may be part of an operating system or a specific application, component, program, cell, object, or sequence of instructions. The computer program of the present invention typically is comprised of a multitude of instructions that will be translated by a computer into a machine-readable format and hence executable instructions. Also, programs are comprised of variables and data structures that either reside locally to the program or are found in memory or on storage devices. In addition, various programs described hereinafter may be identified based upon the application for which they are implemented in a specific embodiment of the invention. However, it should be appreciated that any particular program nomenclature that follows is used merely for convenience, and thus embodiments should not be limited to use solely in any specific application identified and/or implied by such nomenclature.

It will be apparent to those skilled in the art having the benefit of this disclosure that the present invention contemplates methods and arrangements to interconnect rack equipment and make for easy access to components of such equipment while the rack equipment is operating. It is understood that the form of the invention shown and described in the detailed description and the drawings are to be taken merely as examples. It is intended that the following claims be interpreted broadly to embrace all the variations of the example embodiments disclosed.

Although the present invention and some of its advantages have been described in detail for some embodiments, it should be understood that various changes, substitutions and alterations can be made herein without departing from the spirit and scope of the invention as defined by the appended claims. Although an embodiment of the invention may achieve multiple objectives, not every embodiment falling within the scope of the attached claims will achieve every objective. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An equipment mounting apparatus comprising:
a first rigid member securable in a rack perpendicular to vertical members in the rack, the first rigid member having a first end and a second end;
a second rigid member configured to slidably engage the first rigid member, the second rigid member attachable to an insertable chassis; and
a plurality of electrical conductors assembleable in a parallel relationship with the first rigid member such that contacts mounted on the insertable chassis can contact with the plurality of electrical conductors as the insertable chassis and the second rigid member are moved to at least two positions in relation to the first rigid member.

2. The apparatus of claim 1, further comprising ball bearings between the first rigid member and the second rigid member.

3. The apparatus of claim 1, further comprising a printed circuit board to mount the electrical conductors in the parallel relationship with the first rigid member.

4. The apparatus of claim 1, further comprising a first contact housings located proximate to the first end of the first rigid member and a second contact housing located proximate to the second end of the first rigid member wherein the first and second contact housings are located in a parallel relationship with the first and second end of the first rigid member.

5. The apparatus of claim 1, wherein the plurality of isolated contacts are strips of copper, the strips having a length and a width, wherein the length of the strips as over ten times the width.

6. The apparatus of claim 1, wherein the contacts are spring loaded to bias the contacts towards the conductors.

7. The apparatus of claim 1, wherein the conductors are spring loaded to bias the conductors towards the contacts.

8. The apparatus of claim 1, wherein the conductors are aligned in a linear configuration from the first end to the second end of first rigid member.

9. The apparatus of claim 1, further comprising:
a third rigid member securable in the rack perpendicular to the vertical members in the rack, the third rigid member having a first end and a second end;
a fourth rigid member configured to slidably engage the third rigid member and attachable to the insertable chassis; and
a second set of electrical contacts, assembleable in a parallel relationship with the third rigid member such that conductors mounted on a second side of the insertable chassis can contact with the second set of electrical contacts as the insertable chassis and the fourth rigid member is moved to at least two positions in relation to the third rigid member.

10. An equipment mounting system comprising:
a first rail mountable horizontally between a first and second vertical member in an equipment rack, the equipment rack having a periphery;
a second rail mounted horizontally between a third and fourth vertical member in the equipment rack, the first and second rail to guide an equipment chassis as the chassis is inserted into the equipment rack; and
a set of contacts disposed in a parallel configuration with the first rail such that a set of conductors mounted on the equipment chassis can engage the set of contacts when the chassis is inserted into the rack and the set of conductors can engage the set of contacts when a portion of the chassis is outside of the periphery of the rack.

11. The equipment mounting system of claim 10, wherein the set of contacts is configured to carry signals in accordance with a uniform serial bus specification.

12. The equipment mounting system of claim 10, further comprising a circuit board to interconnect the set of contacts with at least one other set of contacts associated with another equipment mount.

13. The equipment mounting system of claim 10, further comprising ball bearings disposed between the first rail and the second rail.

14. A method of manufacturing an equipment rail comprising:
forming a first rigid member;
forming a second rigid member to slidably engage the first rigid member; and
forming a set of contacts to be assembled proximate to the first rigid member and in a parallel configuration with the first rigid member such that when conductors coupled to the second rigid member move with the second rigid member along the first rigid member, the set of contacts can engage the conductors proximate to the second rigid member in more than one location.

15. The method of claim 14, further comprising aligning an equipment chassis with the second rigid member.

16. The method of claim 14, further comprising making a printed circuit board that secures the set of contacts proximate to the first rigid member.

17. The method of claim 16, further comprising assembling a connector onto the printed circuit board.

18. The method of claim 14, further comprising connecting the set of contacts with an interconnect module that is disposed from a first rail to a second rail.

19. The method of claim 14, further comprising assembling a friction reducing apparatus between the first rail and the second rail.

20. The method of claim 14, further comprising sliding an equipment chassis connected to the second rail out of the rack and testing components contained in the chassis when the chassis is extended and operating outside of the rack.
